(19) United States
(12) Patent Application Publication
(10) Pub. No.: US 2008/0061448 A1
(43) Pub. Date: Mar. 13, 2008

(54) SYSTEM AND METHOD FOR THERMAL EXPANSION PRE-COMPENSATED PACKAGE SUBSTRATE

(75) Inventors: Martin P. Goetz, Cary, NC (US); Jennifer V. Muncy, Ridgefield, CT (US)

Correspondence Address: CANTOR COLBURN LLP - IBM RESEARCH TRIANGLE PARK, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/530,925

(22) Filed: Sep. 12, 2006

(51) Int. Cl. H01L 23/13; H01L 21/58

(52) U.S. Cl. 257/779; 438/106; 438/125; 257/787

(57) ABSTRACT

A system and method for manufacturing a thermal expansion pre-compensated package system. The system including a substrate having a first and a second planar surface. The first planar surface being opposed to the second planar surface. The system further including a mold compound having a third and a fourth planar surface. The fourth planar surface affixed to the first planar surface of the substrate to provide a low stress interface. A cavity is formed in the third planar surface of the mold compound.

### TRADEMARKS

IBM® is a registered trademark of International Business Machines Corporation, Armonk, N.Y. U.S.A. Other names used herein may be registered trademarks, trademarks or product names of International Business Machines Corporation or other companies.

### BACKGROUND OF THE INVENTION

1. Field of Invention

This invention relates in general to an electrical interconnection arrangement for making connection between electronic devices. More particularly, the invention relates to a substrate used to provide an interconnection from an electrical device, the substrate maintains a mold compound on one side such that the substrate and mold compound is subjected to a particular stress/strain.

2. Description of Background

One of the problems encountered with integrated circuit connections to the next level of packaging is the high stress/strain on the interconnections caused by coefficient of thermal expansion mismatch. Known solutions exist to counter this problem, such as providing a mechanical and/or material constraint through the use of underfill epoxies or metal seal rings. The drawbacks to such solutions are numerous, including the cost of materials, tooling, processing and marginal reliability improvements.

Thus, there is a need for an additional solution to provide a packaged integrated circuit using standard materials and assembly processes to ensure a highly reliable, thermally compensated interface.

### SUMMARY OF THE INVENTION

The shortcomings of the prior art are overcome and additional advantages are provided through the provision of a thermal expansion pre-compensated package system. The system includes a substrate having a first and a second planar surface. The first planar surface is opposed to the second planar surface. The system further includes a mold compound having a third and a fourth planar surface. The fourth planar surface is affixed to the first planar surface of the substrate to provide a low stress interface. A cavity is formed in the third planar surface of the mold compound.

The shortcomings of the prior art are overcome and additional advantages are provided through the provision of a method for manufacturing a thermal expansion pre-compensated package system. The method includes producing a substrate and affixing a mold compound to the substrate to provide a low stress interface. Then forming a cavity in the mold compound.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### Technical Effects

As a result of the summarized invention, technically we have achieved a solution for a system and a method for manufacturing a thermal expansion pre-compensated package system.

### BRIEF DESCRIPTION OF THE DRAWINGS

The subject regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates one example of a substrate, in accordance with an embodiment of the present invention;

FIG. 2 illustrates one example of a mold compound affixed to the substrate shown in FIG. 1;

FIG. 3 illustrates one example of a cavity disposed in the mold compound shown in FIG. 2;

FIG. 4 illustrates one example of a circuit disposed in the cavity shown in FIG. 3;

FIG. 5 illustrates one example of the circuit affixed to the combination of the mold compound and the substrate shown in FIG. 4;

FIG. 6 illustrates one example of an alternative embodiment of the circuit affixed to the combination of the mold compound and the substrate shown in FIG. 5;

FIG. 7 illustrates one example of an alternative embodiment of the mold compound shown in FIG. 3;

FIG. 8 illustrates one example of the circuit disposed on the combination of the mold compound and the substrate shown in FIG. 7;

FIG. 9 illustrates one example of the circuit affixed to the combination of the mold compound and the substrate shown in FIG. 8;

FIG. 10 illustrates one example of an alternative embodiment of the circuit affixed to the combination of the mold compound and the substrate shown in FIG. 9;

FIG. 11 illustrates one example of an alternative joining of the substrate and the mold compound shown in FIG. 2;

FIG. 12 illustrates one example of an alternative mold compound shown in FIG. 11;

FIG. 13 illustrates one example of the circuit being joined to the substrate shown in FIG. 12;

FIG. 14 illustrates one example of the circuit being adhesively joined to the substrate shown in FIG. 13;

FIG. 15 illustrates one example of an alternative embodiment of the circuit and the substrate shown in FIG. 14;

FIG. 16 illustrates one example of an alternative embodiment of the circuit and the substrate shown in FIG. 15;

FIG. 17 illustrates one example of an alternative embodiment of the circuit and the substrate in FIG. 16;

FIG. 18 illustrates one example of an alternative embodiment of the circuit and the substrate of FIG. 17; and

FIG. 19 illustrates one example of an alternative embodiment of the circuit and the substrate of FIG. 18.

The detailed description explains the preferred embodiment of the invention, together with advantages and features, by way of example with reference to the drawings.

### DETAILED DESCRIPTION OF THE INVENTION

The disclosed invention solves the problem of circuit-package interaction by pre-compensating the package substrate thermal expansion before circuit assembly to the substrate. A substrate used to provide interconnect from a device, such as a semiconductor or integrated circuit (IC), etc., is injection molded with a mold compound on one side of the substrate. The type of mold compound, the geometry and the thickness is predetermined so the substrate and mold compound composite will be under a particular stress/strain. The result will be a pre-compensated package that will provide a low-stress interface between the IC device and the substrate. When the IC is attached to the substrate via a solder bump or other electrical connection and subjected to an elevated temperature reflow profile, the difference in the thermal expansion between the different materials (IC, solder bump, substrate) will be minimized. The stress/strain associated with the difference in thermal expansion of the interfaces will also be minimized.

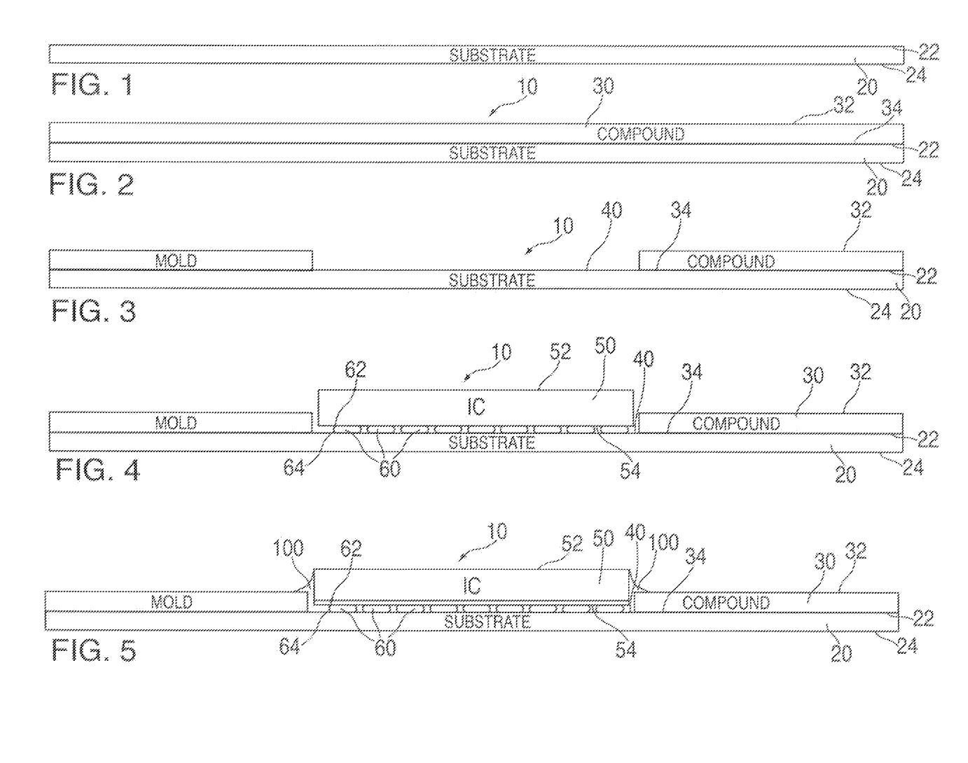

Referring initially to FIGS. 1 and 2, a thermal expansion pre-compensated package system 10 is shown. The system 10 includes a substantially flat substrate 20, which is formed from multi-layered laminations of alternating disposed dielectric and conductive layers. The substrate 20 includes a first planar surface 22 and a second planar surface 24. The first planar surface 22 and the second planar surface 24 are parallel and opposed to each other.

The system 10 further includes a substantially flat mold compound 30 including a third planar surface 32 and a fourth planar surface 34. The fourth planar surface 34 is affixed to the first planar surface 22 of the substrate 20 to provide a low stress/strain interface. The type of mold compound 30, the geometry and the thickness are predetermined so that the substrate 20 and the mold compound 30 are subjected to a particular stress/strain.

Referring to FIG. 3, the mold compound 30 has been further formed to include a cavity 40. The cavity 40 is formed in the third planar surface 32 of the mold compound 30 such that a circuit 50 having a fifth planar surface 52 and a sixth planar surface 54 may be disposed within the cavity 40, as shown in FIG. 4. The circuit 50 is electrically coupled to the supporting substrate 20. The circuit 50 may be a semiconductor, an integrated circuit, etc.

Referring to FIG. 4, the system 10 further includes a plurality of solder bump pads 60. Each solder bump pad 60 includes a top surface 62 and a bottom surface 64. The top surface 62 of each solder bump pad 60 is affixed to the sixth planar surface 54 of the circuit 50. The bottom surface 64 of each solder bump pad 60 is affixed to the first planar surface 22 of the substrate 20 such that the solder bump pads 60 form a mechanical and an electrical connection between the circuit 50 and the substrate 20.

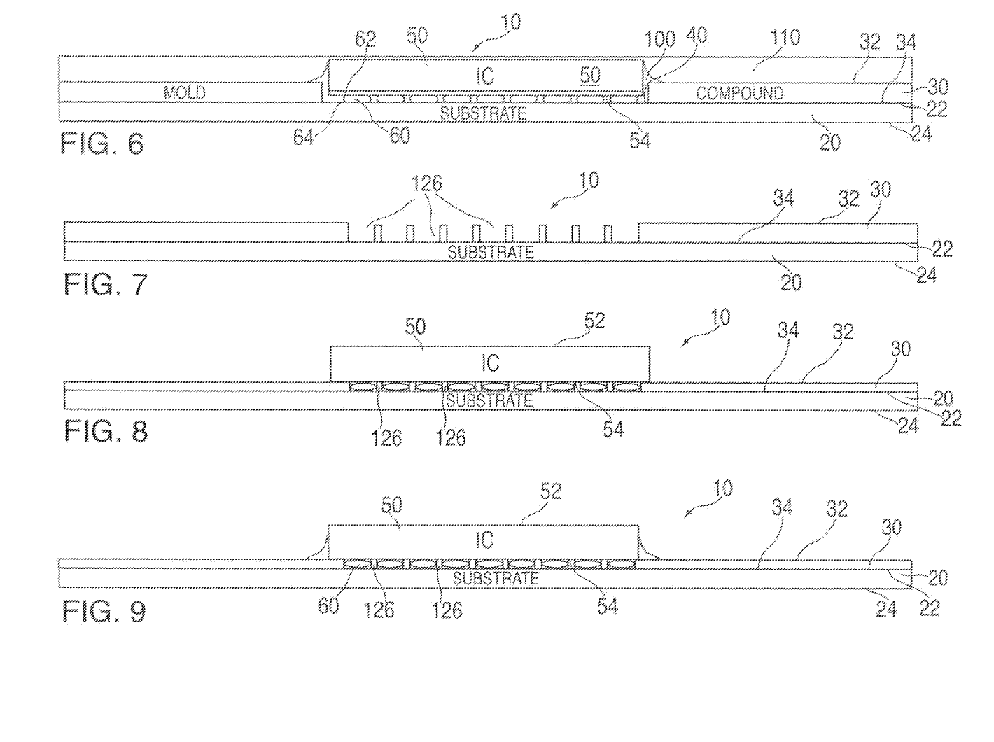

Referring to FIG. 5, the cavity 40 is filled with an adhesive layer 100 to reinforce the mechanical connection between the circuit 50 and the mold compound 30. Optionally, the circuit 50 may be encapsulated by applying an epoxy layer 110 over the combination of the circuit 50 and the mold compound, as shown in FIG. 6. The epoxy layer 110 provides high strength and further bonds the circuit 50 to the substrate 20 to further minimize stress at the solder connections during thermal cycling.

Referring to FIG. 7, an alternative embodiment of the mold compound 30 is shown. As previously explained, the mold compound 30 includes the third planar surface 32 and the fourth planar surface 34. This embodiment of the mold compound 30 further includes a plurality of cavities 126 that are spaced apart and aligned with one another.

The substrate 20 including the first planar surface 22 and the second planar surface 24 is affixed to the mold compound 30. More particularly, the first planar surface 22 of the substrate 20 is affixed to the fourth planar surface 34 of the mold compound 30 to provide a low stress/strain interface. As previously explained, the type of mold compound 30, the geometry and the thickness are predetermined so that the substrate 20 and the mold compound 30 are subjected to a particular stress/strain.

Referring to FIG. 8, the circuit 50 is disposed on top of the mold compound 30. Particularly, the sixth planar surface 54 of the circuit 50 is disposed on the third planar surface 32 of the mold compound 30. The circuit 50 is electrically coupled to the supporting substrate 20.

Referring to FIG. 9, the plurality of solder bump pads 60 are shown. The solder bump pads 60 are disposed in the cavities 126. The top surface 62 of each solder bump pad 60 is affixed to the sixth planar surface 54 of the circuit 50, such that the solder bump pads 60 form a mechanical and an electrical connection between the circuit 50 and the substrate 20.

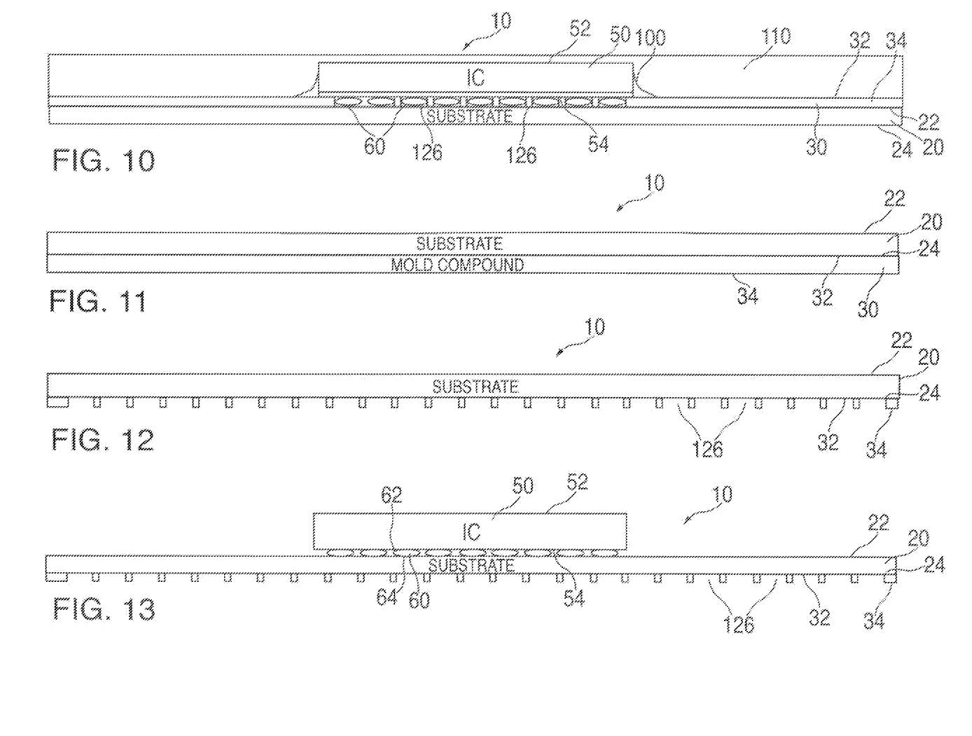

The adhesive layer 100 is applied to the circuit 50 to affix the circuit 50 to the third planar surface 32 of the mold compound 30 to reinforce the mechanical connection between the circuit 50, the substrate 20 and the mold compound 30. Optionally, the circuit 50 may be encapsulated by applying the epoxy layer 110 over the combination of the circuit 50 and the mold compound 30, as shown in FIG. 10. The epoxy layer 110 provides high strength and further bonds the circuit 50 to the substrate 20 to further minimize stress at the solder connections during thermal cycling.

Referring to FIG. 11 an alternative embodiment of the disclosed invention is shown. In this embodiment, the substrate 20 is disposed upon the mold compound 30 as compared to the previous embodiment wherein the mold compound 30 has been disposed upon the substrate 20. More particularly, the second planar surface 24 of the substrate 20 is affixed to the third planar surface 32 of the mold compound 30.

Referring to FIG. 12, the plurality of cavities 126 are formed in the fourth planar surface 34 of the mold compound 30 such that the bottom side electrical pads of the substrate 20 are exposed.

Referring to FIG. 13, the sixth planar surface 54 of the circuit 50 is disposed upon the top surface 62 of the solder bump pads 60 and the bottom surface 64 of the solder bump pads 60 is disposed upon the first planar surface 22 of the substrate 20.

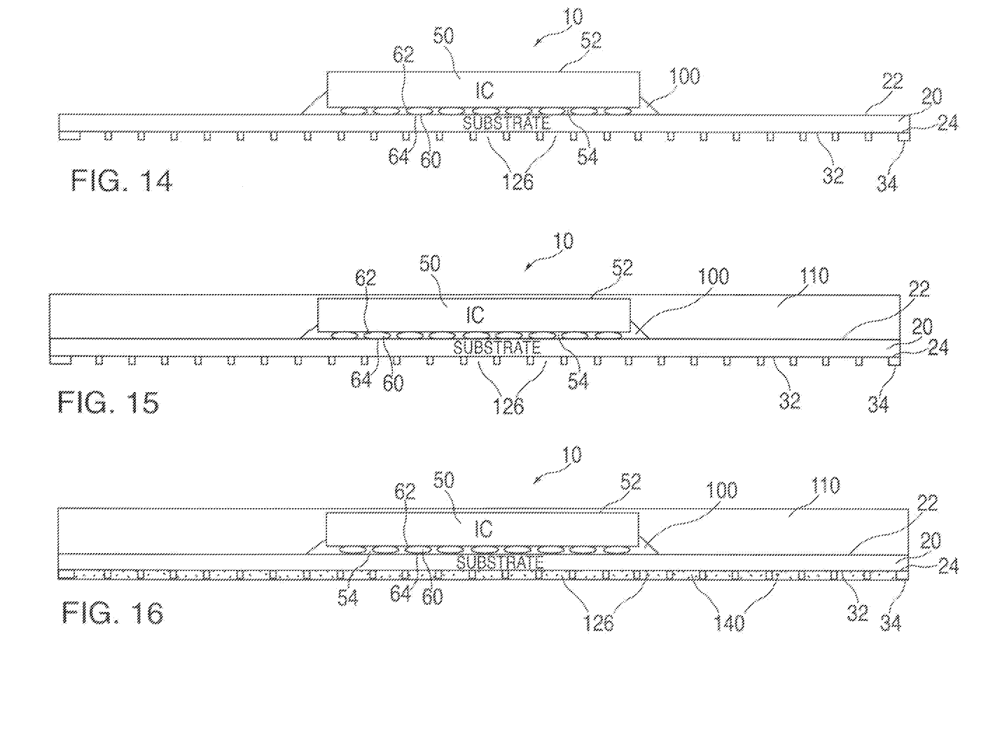

Referring to FIG. 14, the circuit 50 is adhesively joined via the adhesive layer 100 to the first planar surface 22 of the substrate 20. Optionally, as shown in FIG. 15, the circuit 50 may be encapsulated by adding the epoxy layer 110 over the combination of the circuit 50 and the substrate 20. Furthermore, a low modus conductive material 140 may optionally be used to fill the cavities 126 in the mold compound 30 as shown in FIG. 16.

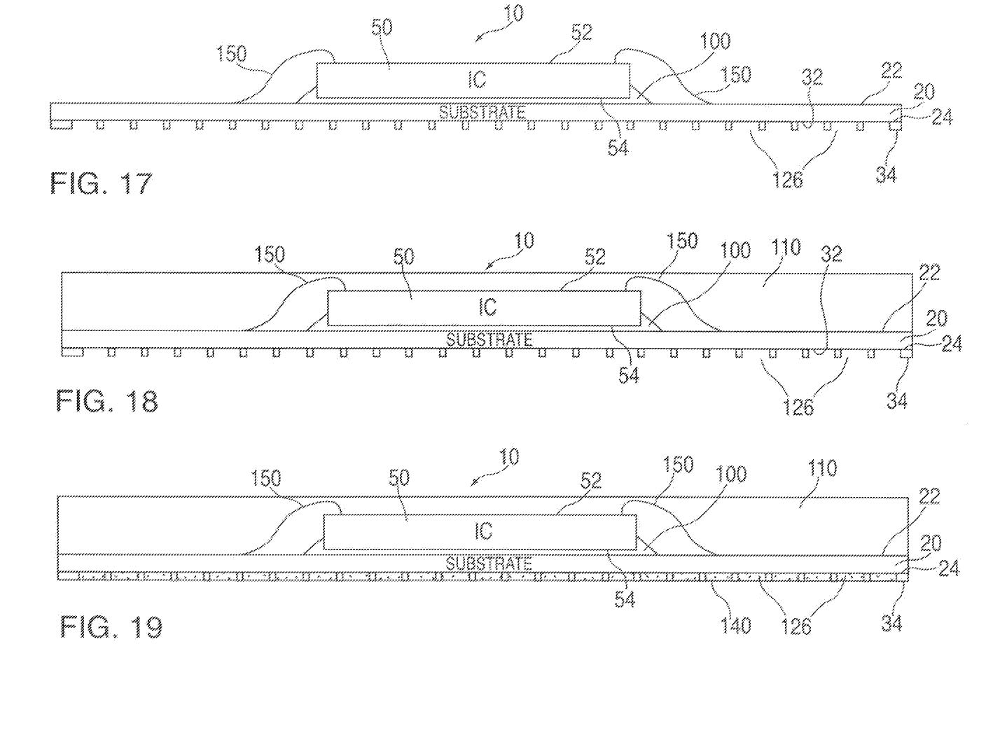

Referring to FIG. 17, an alternative embodiment of the disclosed invention is shown. In this embodiment solder bump pads 60 are not utilized. The circuit 50 is joined via the adhesive layer 100 and via a wirebond 150 to the substrate 20. This embodiment may be encapsulated as previously explained via the epoxy layer 110 being applied over the combination of the circuit 50 and the substrate 20 as shown in FIG. 18. Optionally, the low modus conductive material 140 may be used to fill the cavities 126 in the mold compound 30 as shown in FIG. 19.

Referring to the Figures, a method for manufacturing a thermal expansion pre-compensated package system is shown. A substrate 20 is produced and then a mold compound 30 is affixed to the substrate 20 to provide a low stress/strain interface. Subsequently, a cavity 40 is formed in the mold compound 30.

Then, a circuit 50 is disposed in the cavity 40. Afterwards, a mechanical and an electrical connection between the circuit 50 and the substrate 20 formed. Then the cavity 40 is filled with an adhesive layer 100 to reinforce the mechanical connection between the circuit 50 and the substrate 20. Optionally, the combination of the circuit 50 and the substrate 20 may be encapsulated.

In accordance with an alternative method for manufacturing the thermal expansion pre-compensated package system 10, the combination of the substrate 20 and the mold compound 30 may be formed differently. More particularly, a plurality of cavities 126 may be formed in the mold compound 30. Then the circuit 50 disposed on top of the mold compound 30. Then a mechanical and an electrical connection formed between the circuit 50 and the substrate 20. Then the circuit 50 is adhesively affixed to the substrate 20 and the mold compound 30. Finally and optionally, the combination of the circuit 50 and the substrate 20 may be encapsulated by way of the encapsulation layer 110.

In accordance with an alternative method for manufacturing the thermal expansion pre-compensated package system 10, the combination of the substrate 20 and the mold compound 30 is formed differently. More particularly, the substrate 20 is disposed upon the mold compound 30. Then the plurality of cavities 126, are formed in the fourth planar surface 34 of the mold compound 30 such that the bottom side electrical pads of the substrate 20 are exposed. Then the circuit is disposed upon the top surface 62 of the solder bump pads 60 and the bottom surface 64 is disposed upon the first planar surface of the substrate 20. Then the circuit 50 may be adhesively joined via the adhesive layer 100 to the first planar surface of the substrate 20. Then, optionally, the circuit 50 may be encapsulated by adding the epoxy layer 110 over the combination of the circuit 50 and the substrate 20. Then, optionally also, a low modus conductive material 140 may be used to fill the cavities 126 in the mold compound 30.

In accordance with an alternative method for manufacturing the thermal expansion pre-compensated package system 10, the combination of the substrate 20 and the mold compound 30 is formed differently. In this embodiment the circuit 50 is joined via the adhesive layer 100 and via a wirebond 150 to the substrate 20. This embodiment may optionally be encapsulated by applying the epoxy layer 110 over the combination of the circuit 50 and the substrate 20. Optionally, the low modus conductive material 140 may be used to fill the cavities 126 in the mold compound 30.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A thermal expansion pre-compensated package system, comprising:
a substantially flat substrate having a first and a second planar surface, the first planar surface being opposed to the second planar surface;
a substantially flat mold compound having a third and a fourth planar surface, the fourth planar surface affixed to the first planar surface of the substrate to provide a low stress interface; and
a cavity formed in the third planar surface of the mold compound.

2. The system of claim 1, further including a circuit having a fifth planar surface and a sixth planar surface, the circuit disposed within the cavity.

3. The system of claim 2, further including a plurality of solder bump pads having a top surface and a bottom surface, the top surface of each solder bump pad affixed to the sixth planar surface of the circuit and the bottom surface of each solder bump pad affixed to the first planar surface of the substrate such that the solder bump pads form a mechanical and an electrical connection between the circuit and the substrate.

4. The system of claim 3, wherein the cavity is filled with an adhesive layer to reinforce the mechanical connection between the circuit and the mold compound.

5. The system of claim 4, wherein the circuit is encapsulated by an epoxy layer applied over the combination of the circuit and the mold compound.

6. The system of claim 1, wherein the cavity is segmented into a plurality of cavities formed in the third planar surface, the cavities being spaced apart and aligned with one another.

7. The system of claim 6, further including a circuit having a fifth planar surface and a sixth planar surface, the sixth planar surface of the circuit partially disposed on top of the third planar surface of the mold compound.

8. The system of claim 7, further including a plurality of solder bump pads having a top surface and a bottom surface, each solder bump pad being disposed in one of the plurality of cavities formed in the third planar surface of the mold compound, the top surface of each solder bump pad affixed to the sixth planar surface of the circuit such that the solder bump pads form a mechanical and an electrical connection between the circuit and the substrate.

9. The system of claim 8, wherein the circuit is adhesively affixed by an adhesive layer to the third planar surface of the mold compound to reinforce the mechanical connection between the circuit and the mold compound.

10. The system of claim 9, wherein the circuit is encapsulated by an epoxy layer applied over the combination of the circuit and the mold compound.

11. A method for manufacturing a thermal expansion pre-compensated package system, comprising:
producing a substantially flat substrate;
affixing a substantially flat mold compound to the substantially flat substrate to provide a low stress interface; and
forming a cavity in the mold compound.

12. The method of claim 11, further comprising:
disposing a circuit in the cavity.

13. The method of claim 12, further comprising:
forming a mechanical and an electrical connection between the circuit and the substrate.

14. The method of claim 13, further comprising:
filling the cavity with an adhesive to reinforce the mechanical connection between the circuit and the mold compound.

15. The method of claim 14, further comprising:
encapsulating the combination of the circuit and the mold compound.

16. The method of claim 1, further comprising:
forming a plurality of cavities in the cavity of the mold compound.

17. The method of claim 16, further comprising:
disposing a circuit on top of the mold compound.

18. The method of claim 17, further comprising:
forming a mechanical and an electrical connection between the circuit and the mold compound;
affixing via an adhesive the circuit to the mold compound; and
encapsulating the combination of the circuit and the mold compound.
